(19) United States
(12) Patent Application Publication
(10) Pub. No.: US 2014/0210448 A1
(43) Pub. Date: Jul. 31, 2014

(54) SYSTEM AND METHOD FOR DETERMINING RADIATION ABSORPTION

(71) Applicant: DANIEL D. BRUNDA, EWING, NJ (US)

(72) Inventor: DANIEL D. BRUNDA, EWING, NJ (US)

(21) Appl. No.: 13/750,411

(22) Filed: Jan. 25, 2013

(51) Int. Cl. G01R 29/08

(52) U.S. Cl. CPC G01R 29/0857
USPC 324/72

(57) ABSTRACT

Provided is a method and system for measuring the amount of electromagnetic radiation absorbed by a living being at a particular location. Using a clamp meter having a current probe, the probe is applied to an ankle of the living being. Next, a measurement of the current induced by absorption of radiation of the ankle is obtained. A measure of total absorbed radiation can be obtained by first taking the measurement at one ankle of a living being and then at the other ankle(s), and adding the measurements together.

### FIELD OF THE INVENTION

This invention generally relates to the measurement of electromagnetic (non-ionic) radiation emanating from power lines and other devices, and, more particularly, to measurement of the electromagnetic radiation being absorbed by human beings proximate to overhead power lines and/or electronic equipment utilizing electrical energy.

### BACKGROUND OF THE INVENTION

Devices for measuring electromagnetic waves and radiated electromagnetic energy in the low frequency (60 Hz), high frequency, very high frequency, etc. ranges throughout the spectrum, including light waves are well known.

In addition, U.S. Pat. No. 5,350,999, which issued Sep. 27, 1994, entitled “Measurement System and Method for Determining the Amount of Electromagnetic Radiation Energy Being Absorbed by Living Beings”, to Brunda, hereinafter, the “Brunda Patent”, included herein by reference in its entirety, described a system and method for measuring the amount of electromagnetic radiation actually absorbed by a person (a.k.a., a “living being”), rather than simply the amount of such radiation in the person's environment. One complication to the system and method of the Brunda Patent is that the measurement required the use of a ground and multiple readings to be taken.

The Brunda Patent also provides significant information regarding the negative impact of absorbed radiation on a person, and in particular, low frequency 60 Hz radiation from high voltage power lines as well as electronic equipment using the standard 110 and 220 volt, 60 Hz power. Since the filing of the Brunda Patent, numerous additional studies and references have been performed, with some confirming the negative effects of a person's exposure to electromagnetic radiation, and even broadening the range of frequencies at which these effects occur. For additional background information on the effects of electromagnetic radiation on human beings, see “The Universal Plague: Power Line Radiation, Hereditary Diseases, the Unified Nature of Electromagnetic Radiation Energy and Control and the Radiation Limits of Human Beings”, by Daniel Donald Brunda DDG LFIBA MOIF IOM AdVSci, PA, ISBN 978-1-4134-3084-4, Library of Congress Control Number 2003096678, hereinafter the “Brunda Publication”, also included herein by reference.

It is clear from these and other references and studies that electromagnetic radiation absorbed by a living person may have a deleterious effect on their health and well-being. It would therefore be useful to provide for a determination as to the actual amount of such radiation absorbed by a person, and not simply rely on environmental readings of the radiation exposure.

A table initially published by Underwriter Laboratories and also provided at page 23 of “The Design of Safe Electric Transmission and Distribution Lines”, also by Daniel Donald Brunda DDG LFIBA MOIF IOM AdVSci, PA, ISBN 978-1-4010-8922-1, Library of Congress Control Number 2002096706 provides a short list of observed damages to human beings at different levels of electrical current. This table is reproduced in part here:

TABLE 1
The Effects of Current on the Human Body

| | |
|---|---|
| 1 mA or less | No sensation, not felt |
| More than 3 mA | Painful shock |
| More than 10 mA | Local muscle contraction, sufficient to cause |
| | “freezing” to the Circuit for 2.5 percent of the |
| | population |
| More than 15 mA | Local muscle contraction, sufficient to cause |
| | “freezing” to the Circuit for 50 percent of th |
| | population |
| More than 30 mA | Breathing is difficult, can cause unconsciousness |
| 50 mA to 100 mA | Possible ventricular fibrillation of the heart |
| 100 mA to 200 mA | Certain ventricular fibrillation of the heart |
| More than 200 mA | Severe burns and muscular contractions, |
| | heart more apt to stop than to go into fibrillation |
| More than a few amps | Irreparable damage to body tissues |
| 6.26 amps | The Electric Chair (2000 Volts) - 296 Ohms |
| | (79.4 Joules) |

Thus, there is a need for a system and method for fast and accurate determination of the current induced by electromagnetic radiation being absorbed by a living person. The currently accepted threshold for perception of induced currents in human beings is approximately 1 milliamp.

### SUMMARY OF THE INVENTION

An aspect of the present invention provides a method and system for measuring the amount of electromagnetic radiation absorbed by a living being at a particular location. Using a clamp meter having a current probe, the probe is applied to a body part of the living being. Next, a measurement of the current induced by absorption of radiation of the body part is obtained.

In one aspect of the invention the current probe is a flexible current probe.

In another aspect of the invention, the method and system provides for a measurement of the total radiation absorbed by a living body by first measuring the current induced in one ankle of the body, then measuring the current induced in the other ankle of body (for a two legged living body) and adding the current measurements together. Thus, I_{T}=I₁+I₂; where I_{T} is total induced current, I₁ is measurement obtained from the first ankle, and I₂ is the measurement obtained from the second ankle.

To measure total radiation absorbed for a four-legged living body, add in measurements from the third and fourth ankles.

### BRIEF DESCRIPTION OF THE DRAWINGS

FIG. 1 is a pictorial schematic representation of electromagnetic radiation emanating from overhead power transmission lines and electronic equipment impinging upon a biological equivalent circuit of a living being, which is useful for understanding an embodiment of the present invention;

FIG. 2 is a pictorial representation of a living being showing an exemplary system and method for obtaining the radiation absorption measurements, in accordance with an embodiment of the present invention;

### DETAILED DESCRIPTION

In the following description, for purposes of explanation, specific numbers, materials and configurations are set forth in order to provide a thorough understanding of the invention. It will be apparent, however, to one having ordinary skill in the art, that the invention may be practiced without these specific details. In some instances, well-known features may be omitted or simplified so as not to obscure the present invention. Furthermore, reference in the specification to “one embodiment” or “an embodiment” means that a particular feature, structure or characteristic described in connection with the embodiment is included in at least one embodiment of the invention. The appearances of the phrase “in an embodiment” in various places in the specification are not necessarily all referring to the same embodiment.

The terms “living being” and “person” are used interchangeably herein and refer in general to any living entity having ankles and capable of absorbing electromagnetic radiation, without further limitation.

A low frequency (60 Hz) alternating current transmission system, supplying power to industrial environments, homes, etc. for utilization by different types of equipment, as is well known, radiates electromagnetic fields. The power lines, as well as any electronic equipment utilizing this energy are continuously radiating non-ionizing electromagnetic waves that may be absorbed by living beings in close proximity thereto. Many papers have been written with regard to the effect on living beings, especially on the human body, affected by exposure to these radiated waves.

The present invention advantageously provides a simple system and method for obtaining measurements of these absorbed electromagnetic waves so that the relative information obtained will be useful in future studies. The earlier studies made on the effects of electromagnetic radiation such as for example the study entitled: “CASE-CONTROL STUDY OF CHILDHOOD CANCER AND EXPOSURE TO 60-Hz MAGNETIC FIELDS”, made by Doctor David A. Savitz, Howard Wachtel, Frank A. Barnes, Esther M. John and Jiri G. Tvrdik published in the American Journal of Epidemiology, copyright 1988 by The Johns Hopkins University School of Hygiene and Public Health (which is incorporated herein in its entirety), did not measure the radiation absorbed by human beings. However, correlation between different studies may be readily made with ease, since a simple method and apparatus is now available to obtain the measurements.

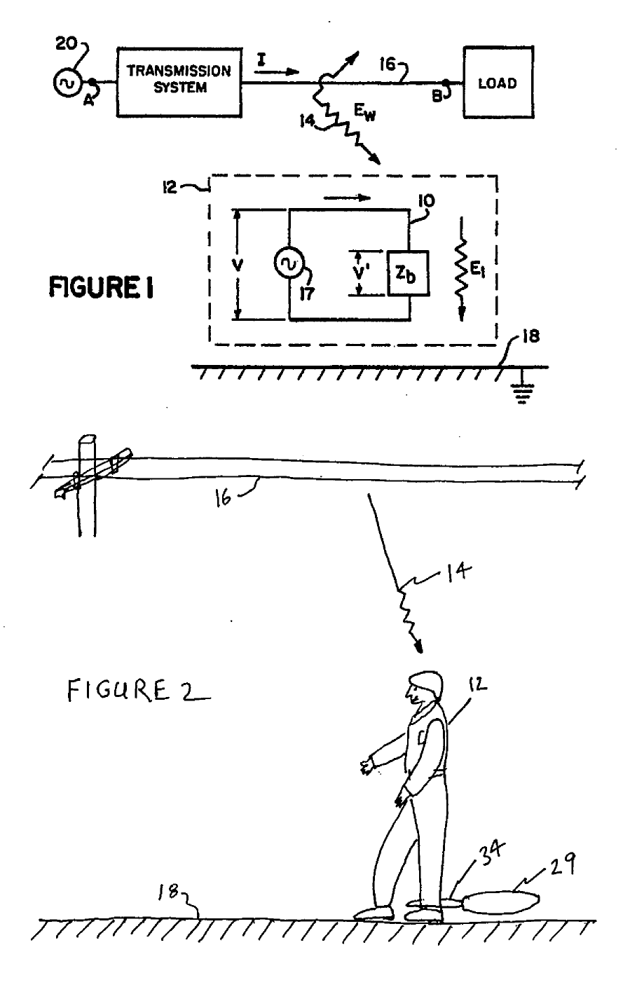

Referring now to FIG. 1, which shows a pictorial schematic representation of inductive coupling of a biological circuit 10 of a human body 12, illustrated in block form, from an external electromagnetic field (E_{w}) 14 produced by an overhead power transmission line 16. The reactive impedance of the body 12 may be represented by Z_{b}. The body power source 17 represented by the symbol V causes a current i to flow in the circuit for the body 10.

When the body 12 is introduced into the field 14 by appearing beneath power line 16, the body 12 experiences an increased electric current flow i′. Inside the body 12, there takes place a voltage drop V′ to which there corresponds an internal electric field 18 (Eᵢ) that is generally different from the external electric field E_{w}, associated with the field 14. The body's surface causes a distortion of the external electromagnetic field 14 with considerable local variations that depend on the curvature radii of the various parts of the living being 10 and on its dielectric characteristics.

Human beings are sensitive to the electromagnetic field 14 primarily because of the low inductive body impedance, especially in the water, blood, bone, muscle and tissues. Conducting objects placed in the electromagnetic field 14 can modify and enhance the field. The magnitude of the enhancing effect depends on the shape and orientation of the conducting object. For the human body 10 not in contact with ground 18, the electromagnetic field 14 is enhanced immediately about the head to 15 to 20 times that of the undisturbed field. Approximately one-third of the body current it enters the head. Low bodily impedance Z_{b} permits the electromagnetic field 14 to induce electrical current i′ in the head and the entire body, the current being conducted throughout the body by the water, blood, bone, muscle and tissues.

The human brain operates at frequencies ranging from 1 Hz to 300 Hz with high concentrations of electromagnetic radiation at 1 Hz to 51 Hz. The electromagnetic field 14 when at a relatively low frequency is absorbed by the electrical circuits of the brain, the heart and the nervous system of the body 12 and by virtue of the resonant circuits found therein generates circulating currents much greater than the non-resonant parts of the human body 12. This current i′ caused by the inductive coupling causes the normal electrical control currents of the body (i) to be supplemented (increased) to i+i′ by electromagnetic radiation resulting in the heart rate and blood pressure being disturbed by the added current (i′).

To define an inductive coupling model for the human body 12 subjected to an electromagnetic field 14 calls for an initial approximation. The presence of a biological equivalent circuit 10 of the human body 12 occurs by an analogy. The electromagnetic field 14 is capable of inducing a current in wires and cables of nearby electrical systems, regardless of the nature of the source or the type of conductor. In the biological equivalent circuit 10 of the human body 12, blood vessels serve as electric conductor paths (cables), blood serves as one segment of the electrical conductor in the circuit 10, and interstitial fluid, i.e., the fluid between the cells of tissue, serve as another. Since all tissues are irrigated by blood and interstitial fluid, the entire body can be considered as being made up of predominantly essentially homogeneous conducting material.

According to this equivalent model, electrical current (i′) is induced in the human body 12 by the intersecting, alternating electric and magnetic fields formed by the radiated electromagnetic field 14 generated by the current I flowing through, for example, the power line 16 or other nearby device, such as, but not limited to, an electric motor or x-ray machine.

The outer membrane cells have a sufficiently high resistance so that almost all of the current flows around these cells. However, the blood conducting cells and membrane are controlled in part by electric current flow and thus are the sites of a number of physiological processes which are important to cell function.

The power P_{b} induced in the head of the body 12 can be determined by P_{b}=(T²/Z_{b})(24.1/ME)² (E_{c}/P_{c})², wherein ME is a cell or membrane excitation parameter, Z_{b} is the bodily impedance, T is the transfer function, E_{c} is the powerline voltage and P_{c} is the powerline transmitted power.

The method of transferring the power P_{b} from the power lines to the head involves treating the body 12 as having an inductive impedance (Z_{b}) equal to 26 ohms and disposed parallel to the transmission line 16. For example, the transfer of radiated electrical power from the power line 16 to the “parallel” body 12 having blood vessels, etc. therein, assumed to be the same as the transfer of electromagnetic energy from one power transmission line to an adjacent parallel transmission line, not shown.

In the electrical equivalent circuit model for power transmission and coupling therein, the natural frequency of approximately one Hertz the human body's biological equivalent circuit is referred to as f₂. If we assume that this is the natural biological frequency for the human body 12, Then acceptable or preferred radiation level for human beings occurs when:

0<H_{φ}<10 uG

0<f₂<1 Hz

Inductive power coupling transfer function (T) for parallel conductors may be calculated as follows:

(I_{b})ind=E_{w}/f+20 log(I_{c}/E_{w})

(I_{c}E_{w})=E_{c}Zb/12,600ME

(I_{c}E_{w})=24.1/ME=13,200 V(23 ohms)/12,600ME(μw/M)

I_{c}=(24.1/ME)[1/(E_{w}/f²)]=E_{c}/Z_{c}

Ec=(24.1/ME)(Z_{c}/E_{w}/f²)

P_{b}=E_{b}²/Z_{b}=(24.1/ME)2(E_{c}/P_{c})²(T²/Z_{b});
Where T=E_{b}/E_{w}/f²)L
   From actual measurements the following was obtained:

Log P_{b}=2 Log T+2 Log(E_{w}/f²)−Log Z_{b}

Log T=0.5−(Log(E_{w}/f²)+1.0]

Log T+Log(E_{w}/f²)=−0.5

T=E_{b}/E_{w}/f²)L
Therefore, E_{b}=316.2 mv
And Pb=4347 μw, which is not an acceptable level.

The calculations shown above show that an unshielded 13.2 kv power line at 30 meters provides a radiated power which is not acceptable. An attempt to determine the maximum acceptable power line voltage (4,000 volts) to obtain the acceptable radiation absorption level at 30 meters is shown below:

(I_{c}Ew) at 5 kv=5000(23)/12,600−9.13/ME(μw/m)

And (P_{b}) at a maximum of 5 kv=(9.13/ME)²(E_{c}/P_{c})²(T²/Zb)

(P_{b})max=43.47 microwatts for E_{c}=5000 volts at 30 meters.

Therefore, it is advisable to obtain readings of the electromagnetic radiation occurring at a particular location where living beings are to be present.

Referring now to FIG. 2 which shows a human being 12 absorbing radiation from a power line 16 appearing overhead by means of the radiated energy 14 given by the equation:

P_{b}=E_{b}²/Z_{b}

entering the body of the human being 12. If the living being (human 12) is effectively above a common ground 18 by some insulated material 22 e.g. non-conducting rubber shoes, carpeting, etc., etc., then the human being is absorbing the radiated electromagnetic energy.

An embodiment of the present invention utilizes a Fluke 381 clamp meter 29 manufactured by the Fluke Corporation of Everett, Wash. A flexible current probe 34 is applied around a living being's ankle and a reading is then taken of the current passing through the ankle. A non-flexible current probe (not depicted) may alternatively be used. Also, another part of the living body may be measured, although the ankles are particularly useful for determining the total absorbed radiation, as will be further explained herein.

In order to determine the total radiation absorbed by the living being, a measurement may be made at each ankle and the measurements added together (for a two-legged living being). The ankle is a good location at which to measure because ankles have the highest current density, thereby providing limited shielding from the detection instrumentality.

Although the invention herein has been described with reference to particular embodiments, it is to be understood that these embodiments are merely illustrative of the principles and applications of the present invention. It is therefore to be understood that numerous modifications may be made to the illustrative embodiments and that other arrangements may be devised without departing from the spirit and scope of the present invention as defined by the appended claims.

1. A method of measuring the amount of electromagnetic radiation absorbed by a living being at a particular location, the method comprising the steps of:
applying a current probe of a clamp meter to a first ankle of the living being;
obtaining a measurement of the current induced by absorption of radiation of the first ankle.

2. The method according to claim 1, further comprising:
applying the current probe of the clamp meter to a second ankle of the living being;
obtaining a second measurement of the current induced by absorption of radiation of the second ankle; and,
determining a total amount of radiation absorption according to:
I_{T}=I₁+I₂; where I_{T} is total induced current, I₁ is measurement obtained from the first ankle, and I₂ is the measurement obtained from the second ankle.

3. The method according to claim 2, wherein the current probe is a flexible current probe.

4. A system for measuring the amount of electromagnetic radiation absorbed by a living being at a particular location, the system comprising:
a clamp meter and associated current probe, wherein the flexible current probe is applied to a first ankle of the living being, and a measurement of the current induced by absorption of radiation of the first ankle is obtained.

5. The system according to claim 4, wherein the current probe of the clamp meter is applied to a second ankle, and a second measurement of the current induced by absorption of radiation of the second ankle is obtained; and,
a total amount of radiation absorption is determined according to:
I_{T}=I₁+I₂; where I_{T} is total induced current, I₁ is measurement obtained from the first ankle, and I₂ is the measurement obtained from the second ankle.

6. The system according to claim 5, wherein the current probe is a flexible current probe.
